(19) United States
(12) Patent Application Publication
(10) Pub. No.: US 2024/0412407 A1
(43) Pub. Date: Dec. 12, 2024

(54) SEMICONDUCTOR MANUFACTURING DEVICE AND CONTROL OF THE SAME

(71) Applicant: SAMSUNG ELECTRONICS CO., LTD., Suwon-si (KR)

(72) Inventors: Junghee Cho, Suwon-si (KR); Yunje Cho, Suwon-si (KR); Kwangrak Kim, Suwon-si (KR); Jonghyeok Park, Suwon-si (KR)

(21) Appl. No.: 18/437,115

(22) Filed: Feb. 8, 2024

(30) Foreign Application Priority Data
Jun. 9, 2023 (KR) 10-2023-0073966

(51) Int. Cl. G06T 7/73; G06T 7/00; G06T 7/246; G06T 7/60; H01J 37/09; H01J 37/10; H01J 37/153; H01J 37/22; H01L 21/68

(52) U.S. Cl. CPC G06T 7/73; G06T 7/0004; G06T 7/246; G06T 7/60; H01J 37/09; H01J 37/10; H01J 37/153; H01J 37/222; H01L 21/681; G06T 2207/10061; G06T 2207/10148; G06T 2207/30148; H01J 2237/0455; H01J 2237/1532; H01J 2237/221

(57) ABSTRACT

A semiconductor manufacturing device includes an electron beam source emitting; a plurality of condenser lenses disposed between a stage on which an object including structures is seated and the electron beam source; an objective lens disposed between the plurality of condenser lenses and the stage; an aperture disposed between the plurality of condenser lenses; and a controller configured to acquire a plurality of original images according to a working distance between the objective lens and the object, acquire a pattern image indicating the structures from the plurality of original images, a plurality of kernel images indicating distribution of an electron beam on the object, and a plurality of position vectors indicating a relative position of the structures in the plurality of kernel images, and adjust a position of the aperture based on a motion vector indicating movement of the plurality of position vectors according to the working distance.

### CROSS-REFERENCE TO RELATED APPLICATION(S)

This application claims benefit of priority to Korean Patent Application No. 10-2023-0073966, filed on Jun. 9, 2023, in the Korean Intellectual Property Office, the disclosure of which is incorporated herein by reference in its entirety.

### BACKGROUND

The present disclosure relates to a semiconductor manufacturing device and control of the same.

In a device using an electron beam, such as a scanning electron microscope or the like, it is necessary to accurately irradiate the electron beam to a subject to be analyzed or a subject to be processed. An electron beam emitted from an electron beam source passes through an aperture, a condenser lens formed by an electromagnetic field, or the like, to be incident on a subject. In order to accurately irradiate the electron beam to the subject, a position of the aperture should be controlled such that the electron beam and the aperture are accurately aligned. However, it may take a long time to manually adjust the position of the aperture, thereby reducing efficiency of a process.

### SUMMARY

In general, in some aspects, the present disclosure is directed to a semiconductor manufacturing device and method that can improve process efficiency by automatically controlling a position of an aperture so that an electron beam and the aperture are accurately aligned.

According to some aspects of the present disclosure, a semiconductor manufacturing device includes an electron beam source emitting an electron beam; a plurality of condenser lenses disposed between a stage on which an object including structures is seated and the electron beam source; an objective lens disposed between the plurality of condenser lenses and the stage; an aperture disposed between the plurality of condenser lenses; and a controller configured to acquire a plurality of original images according to change a working distance between the objective lens and the object, acquire a pattern image indicating the structures from the plurality of original images, a plurality of kernel images indicating distribution of the electron beam on the object, and a plurality of position vectors indicating a relative position of the structures in the plurality of kernel images, and adjust a position of the aperture based on a motion vector indicating movement of the plurality of position vectors according to the working distance.

According to some aspects of the present disclosure, a semiconductor manufacturing device includes an electron beam source emitting an electron beam; a lens unit transferring the electron beam generated by the electron beam source to an object; an aperture limiting an electron beam path of the lens unit; and a controller configured to acquire a plurality of original images according to change a working distance between the lens unit and the object, acquire a plurality of position vectors indicating a relative position of structures indicating in the plurality of original images in each of the plurality of original images using the plurality of original images, calculate a motion vector indicating movement of the plurality of position vectors according to the working distance, and adjust a position of the aperture according to a compensation vector determined based on the motion vector.

According to some aspects of the present disclosure, a semiconductor manufacturing device includes an electron beam source configured to emit an electron beam; a plurality of condenser lenses disposed between a stage and the electron beam source, wherein the stage is configured to support an object; an objective lens disposed between the plurality of condenser lenses and the stage; an aperture disposed between the plurality of condenser lenses; and a controller configured to acquire a plurality of original images according to a working distance between the object and the objective lens configured to transfer an electron beam to the object, acquire a single pattern image indicating structures included in the object, acquire a plurality of kernel images indicating distribution of the electron beam on the object, acquire a plurality of position vectors indicating a relative position of the structures in the plurality of original images, from the plurality of original images; acquire a motion vector indicating a movement direction according to the working distance, based on the plurality of position vectors; determine a compensation vector based on the motion vector; and move a position of an aperture limiting an electron beam path of the lens unit based on the compensation vector.

According to some aspects of the present disclosure, a method of controlling a semiconductor manufacturing device includes acquiring a plurality of original images to a working distance between a lens unit transferring an electron beam generated by an electron beam source to an object and the object; acquiring a single pattern image indicating structures included in the object, a plurality of kernel images indicating distribution of the electron beam on the object, and a plurality of position vectors indicating a relative position of the structures in the plurality of original images, from the plurality of original images; acquiring a motion vector indicating a movement direction according to the working distance, based on the plurality of position vectors; determining a compensation vector based on the motion vector; and moving a position of an aperture limiting an electron beam path of the lens unit based on the compensation vector.

### BRIEF DESCRIPTION OF THE DRAWINGS

Exemplary implementations will be more clearly understood from the following detailed description, taken in conjunction with the accompanying drawings.

FIG. 1 is a view illustrating a semiconductor manufacturing device according to some implementations.

FIG. 2 is a view illustrating an electron beam path in a semiconductor manufacturing device according to some implementations.

FIG. 3 is a view illustrating image movement according to aperture alignment of a semiconductor manufacturing device according to some implementations.

FIGS. 4A and 4B are views illustrating images acquired by a semiconductor device according to some implementations.

FIG. 5 is a view illustrating a control method of a semiconductor manufacturing device according to some implementations.

FIGS. 6A to 6C are views illustrating a method of acquiring a plurality of original images according to some implementations.

FIGS. 7 to 9 are views illustrating a method of acquiring a plurality of position vectors from a plurality of original images according to some implementations.

FIG. 10 is a view illustrating a method of acquiring a motion vector from a plurality of position vectors according to some implementations.

FIG. 11 is a view illustrating a motion vector according to a position of an aperture on an X-Y plane.

FIG. 12 is a view illustrating a compensation vector according to a position of an aperture on an X-Y plane.

FIGS. 13A to 13C are views illustrating original images according to a working distance, when a semiconductor manufacturing device has astigmatism.

FIG. 14 is a view illustrating a compensation vector according to a position of an aperture on an X-Y plane, when a semiconductor manufacturing device has astigmatism.

### DETAILED DESCRIPTION

Hereinafter, exemplary implementations will be described with reference to the accompanying drawings.

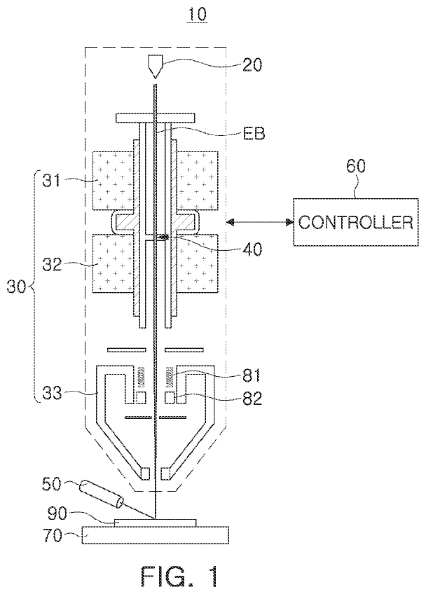

FIG. 1 is a view illustrating an example of a semiconductor manufacturing device.

Referring to FIG. 1, a semiconductor manufacturing device 10 includes a scanning electron microscope (SEM) device. The semiconductor manufacturing device 10 includes an electron beam source 20, a lens unit 30, an aperture 40, a detector 50, a controller 60, and a stage 70.

The semiconductor manufacturing device 10 may irradiate an electron beam EB to an object 90 positioned on the stage 70, and may collect signals emitted from the object 90, to acquire an image of the object 90. For example, the object 90 may be a semiconductor device including structures. In addition, the signals emitted from the object 90 by the electron beam EB irradiated to the object 90 may include signals associated with a secondary electron (SE), a back scattered electron (BSE), an X-ray, visible light, cathodic fluorescence, or the like.

The electron beam source 20 may generate and emit the electron beam EB, in which the electron beam emitted from the electron beam source 20 may be accelerated, condensed by the lens unit 30, and irradiated to the object 90. For example, the electron beam source 20 may include an electron gun, in which the electron gun may heat a filament formed of tungsten or the like to generate an electron, and may accelerate the electron by applying a voltage, to generate the electron beam EB.

The lens unit 30 may include a plurality of condenser lenses 31 and 32, an objective lens 33, and the like. First and second condenser lenses 31 and 32 may condense the electron beams EB emitted from the electron beam source 20 such that the electron beams effectively converge on one point of the object 90. For example, as diameters of the electron beams EB irradiated to the object 90 become smaller, resolution of an image acquired by the controller 70 may be improved. To increase the resolution of the image, the lens unit 30 may include two or more condenser lenses 31 and 32. The diameters of the electron beams EB emitted from the electron beam source 20 may gradually decrease while passing through the first and second condenser lenses 31 and 32.

The objective lens 33 may focus the electron beams EB condensed by the first and second condenser lenses 31 and 32 onto the object 90. For example, the objective lens 33 may determine the diameters of the electron beams EB irradiated onto the object 90. A distance between the objective lens 33 and the object 90 may be defined as a working distance, and the diameters of the electron beams EB irradiated to the object 90 may vary according to the working distance. Therefore, the resolution of the image corresponding to the object 90 may be adjusted by adjusting a position of the objective lens 33.

The objective lens 33 may include a plurality of scan coils 81, an astigmatism adjustor 82, and the like. The plurality of scan coils 81 may deflect the electron beam to one point of the objective lens 33. The astigmatism adjustor 82 may include a plurality of stigmators, and may adjust current flowing through the stigmators, to adjust astigmatism of the electron beam EB passing through the objective lens 33. The objective lens 33 may adjust astigmatism of the lens unit 30 by adjusting the current flowing through the plurality of scan coils 81, or the like, such that the electron beam EB may irradiate the object 90 in a desired shape.

The aperture 40 may be disposed in a path of the electron beam EB, may restrict the path of the electron beam EB to make the electron beam EB incident onto the object 90 uniformly, and may reduce spherical aberration. In the example of FIG. 1, the aperture 40 may be disposed between the first condenser lens 31 and the second condenser lens 32.

The detector 50 may acquire signals emitted from the object 90 due to the electron beam EB irradiating the object 90, and may generate an image using the signals. The image generated by the detector 50 may be transferred to the controller 60.

When the aperture 40 is misaligned with an axis of the electron beam EB, and the lens unit 30 adjusts the working distance between the objective lens 33 and the object 90 to have a desired focus, a phenomenon in which an imaging region of the object 90 moves according to the working distance may occur. When the imaging region moves while the lens unit 30 adjusts focus, it may be difficult to fix a target imaging region, thereby making it difficult to iteratively capture a specific imaging region during automatic imaging.

For example, when the imaging region according to the working distance is not fixed in a wide-area top-down delaying system (W-TDS) device that iteratively images a predetermined imaging region of the object 90 while sequentially removing layers of the object 90 from an upper layer to a lower layer, the imaging region may have to be corrected every time imaging of the layers. Correcting the imaging region takes time, and as a result, the imaging time may increase.

The aperture 40 may be movable at least on an X-Y plane such that the aperture 40 may be aligned with the axis of the electron beam EB. When an operator manually adjusts the aperture 40, it may take a long time, and a degree of accuracy of alignment of the aperture 40 may depend on a skill level of the operator. In addition, when there is astigmatism in the lens unit 30, shapes of imaged structures may change according to the working distance. Therefore, it may be difficult to manually align the aperture 40 accurately by visually checking the imaged structures.

According to some implementations, an operation of optimizing alignment of the aperture 40 in the semiconductor manufacturing device 10 may be automated. Specifically, the controller 60 may acquire a plurality of original images of the object 90 while adjusting the working distance between the objective lens 33 and the object 90. The controller 60 may acquire a motion vector of an image pattern according to the working distance using the plurality of original images, and may acquire a compensation vector for compensating for the position of the aperture 40 based on the motion vector. The controller 60 may automatically optimize the alignment of the aperture 40 based on the compensation vector.

The subject matter of the present disclosure is not limited to a case in which the semiconductor manufacturing device 10 is a scanning electron microscope device, and the semiconductor manufacturing device 10 may be applied to various devices having a lens unit and an aperture and transferring electron beams to an object, such as a transmission electron microscope (TEM) device.

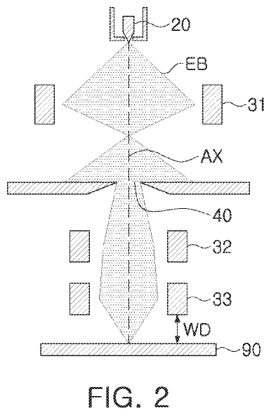

FIG. 2 is a view illustrating an example electron beam path in a semiconductor manufacturing device according to some implementations.

FIG. 2 schematically illustrates a path of an electron beam EB formed by an electron beam source 20, a lens unit 30, and an aperture 40 of a semiconductor manufacturing device 10, as described with reference to FIG. 1.

The electron beam EB output from the electron beam source 20 may be condensed by a first condenser lens 31. The aperture 40 may transfer a portion of the electron beam EB focused by the first condenser lens 31 to a second condenser lens 32. The electron beam EB passing through the aperture 40 may be condensed by the second condenser lens 32, and may be transferred to an objective lens 33. The objective lens 33 may focus the electron beam EB to a point.

The lens unit 30 may adjust a working distance of the objective lens 33 such that a focal point of the objective lens 33 may be located within an imaging region of the object 90. When the working distance and a focal distance of the objective lens 33 are equal to each other, distribution of electron beams within the imaging region may have a circular shape. Also, an image acquired within the imaging region may have patterns in which structures included in the imaging region may be accurately expressed without distortion.

Under an underfocus condition in which the working distance of the objective lens 33 is located closer than the focal distance, and an overfocus condition in which the working distance of the objective lens 33 is located farther than the focal distance, a shape of the electron beam formed in the imaging region may be distorted.

The aperture 40 may limit the path of the electron beam EB to transfer the electron beam EB of a component, perpendicular to a surface of the object 90, to the object 90. Referring to FIG. 2, a vertical axis AX indicating a path, perpendicular to the object 90, among the paths of the electron beam EB, is illustrated. When a position of the aperture 40 is misaligned with the vertical axis AX of the electron beam EB, the axis of the electron beam transferred to the object 90 through the aperture 40 may not be perpendicular to the surface of the object 90, and may have an oblique angle. When the aperture 40 transfers an electron beam having an oblique angle to the object 90, a position of the electron beam formed on the object 90 may be different from those under the underfocus or overfocus condition.

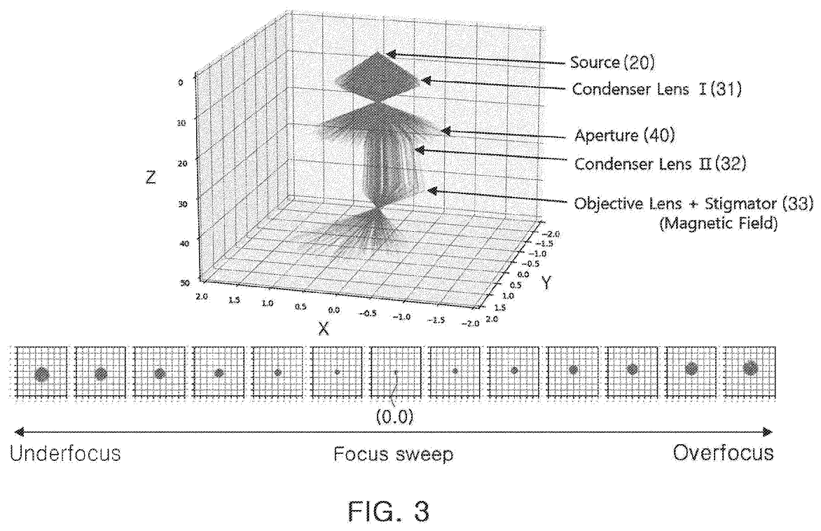

FIG. 3 is a view illustrating image movement according to aperture alignment of a semiconductor manufacturing device according to some implementations.

FIG. 3 illustrates Monte Carlo simulation results for an electron beam path formed by a beam source 20, a lens unit 30, and an aperture 40. Referring to FIG. 3, when a position of the aperture 40 is misaligned with a vertical axis, an electron beam EB having an oblique component to a surface of an object may be transferred to an objective lens 33.

When the objective lens 33 radiates an electron beam having an axis oblique to the surface of the object, an imaging region of the object may move in accordance with a working distance of the objective lens 33. FIG. 3 illustrates kernel images indicating distribution of electron beams in the object according to the working distance of the objective lens 33.

In FIG. 3, when the object is located at a focal distance of the objective lens 33, the electron beams may be focused on a (0, 0) position of an X-Y plane. Under an overfocus condition in which the object is located farther than the focal distance of the objective lens, the electron beams may have a wide distribution, and a center of the distribution of the electron beams may move from the (0, 0) position of the X-Y plane in a first direction. And, under an underfocus condition in which the object is located closer than the focal distance of the objective lens, the center of distribution of the electron beam may move from the position (0, 0) of the X-Y plane in a second direction, opposite to the first direction.

When the position of the aperture 40 is misaligned with the vertical axis, the distribution of the electron beams may move according to the working distance of the objective lens 33, and an imaging position of the object may move according to the working distance of the objective lens 33. The movement of the imaging position of the object according to the working distance of the objective lens 33 may be represented by movement of relative positions of structures appearing in original images captured at different working distances.

According to some implementations, the semiconductor manufacturing device 10 detects relative positions of structures in a plurality of original images acquired by changing the working distance of the objective lens 33, and may acquire a motion vector of the structures to detect misalignment of the aperture 40. In addition, the semiconductor manufacturing device 10 may adjust a position of the aperture 40, based on the motion vector, to control the position of the aperture 40 to be aligned with the vertical axis.

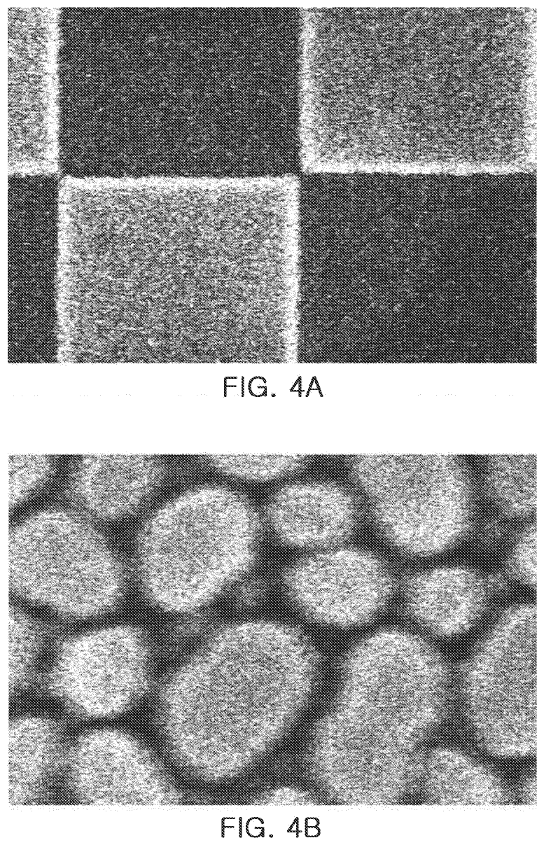

FIGS. 4A and 4B are examples of images acquired by a semiconductor device as described herein.

Referring to FIG. 4A, the image acquired by the semiconductor manufacturing device described herein includes patterns having strong repeatability and weak directionality. Referring to FIG. 4B, the image acquired by the semiconductor manufacturing device described herein includes patterns having non-iterative and irregular shapes.

According to some implementations, position adjustment of an aperture may be automated by detecting, in a plurality of original images, relative positions of structures included in an object being irradiated by an electron beam, regardless of directions and shapes of the structures in the object.

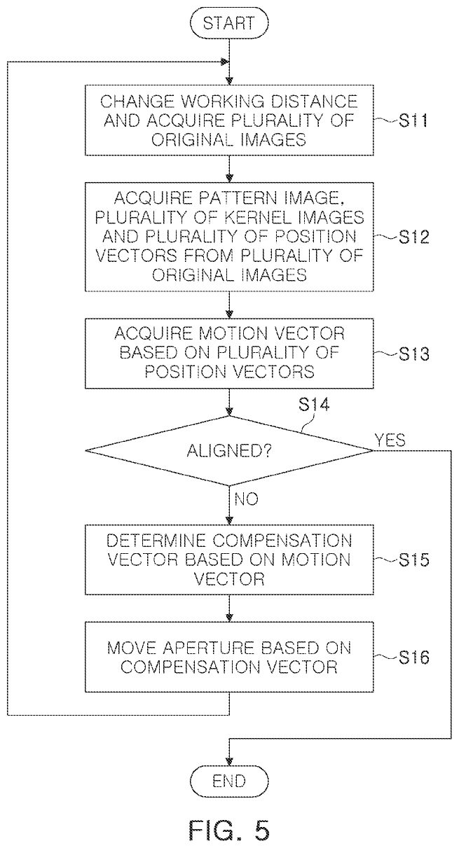

FIG. 5 is a view illustrating a control method of a semiconductor manufacturing device according to some implementations.

In operation S11, a controller of a semiconductor manufacturing device may be configured to change a working distance of an objective lens, and may acquire a plurality of original images according to the working distance. The working distance may be a distance between the objective lens and an object. The plurality of original images may include at least one overfocused image acquired under an overfocus condition in which the working distance is farther than a focal distance, and at least one underfocused image acquired in an underfocus condition in which the working distance may be shorter than the focal distance.

In operation 512, the controller may be configured to acquire a pattern image, a plurality of kernel images, and a plurality of position vectors from the plurality of original images. The pattern image may be an image indicating structures included in a target position to which an electron beam is irradiated on the object. The plurality of kernel images may be images illustrating distribution of electron beams irradiated to the object according to the working distance of the objective lens. Also, the plurality of position vectors may represent relative positions of structures appearing in each of the plurality of original images according to the working distance of the objective lens.

In operation S13, the controller may be configured to acquire a motion vector based on the plurality of position vectors. The motion vector may represent a movement tendency of the plurality of position vectors according to the working distance of the objective lens.

In operation 514, the controller may be configured to determine whether a position of an aperture may be aligned with a vertical axis. For example, when the position of the aperture and the vertical axis are aligned, there will be little change in the plurality of position vectors according to the working distance of the objective lens, and the motion vector may be close to a zero vector.

When a magnitude of the motion vector is less than a threshold value, the controller may be configured to determine that the position of the aperture is aligned with the vertical axis (“yes” in operation S14), and may end the operation. When a magnitude of the motion vector is equal to or greater than the threshold value, the controller may determine that the position of the aperture is misaligned with the vertical axis (“no” in operation S14), and may perform operation S15.

In operation S15, the controller may be configured to determine a compensation vector based on the motion vector. The compensation vector may indicate a movement direction and a movement distance of the aperture for aligning the position of the aperture with the vertical axis.

In operation S16, the controller may be configured to move the aperture based on the compensation vector. In addition, the controller may be configured to determine whether the position of the aperture is aligned with the axis as a result of the movement of the aperture by iteratively performing operations S11 to S14.

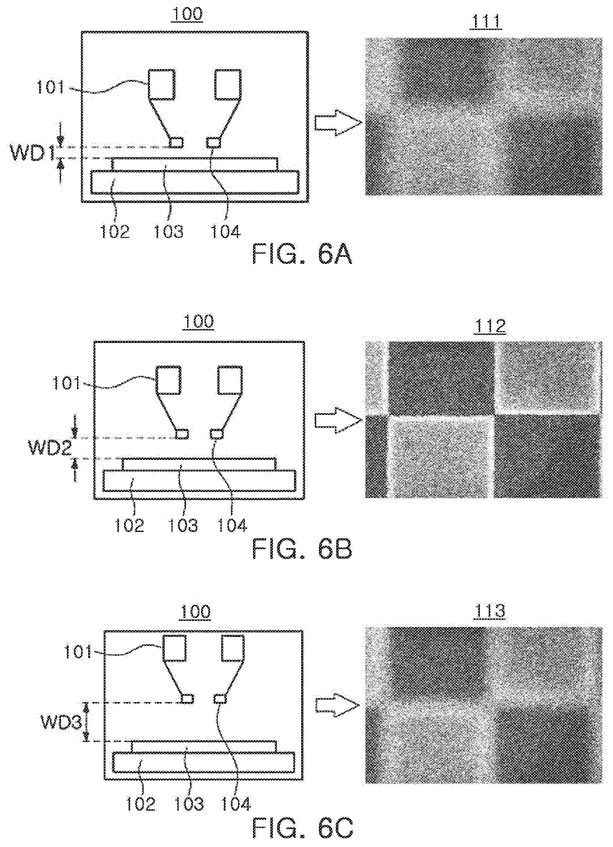

FIGS. 6A to 6C are views illustrating a method of acquiring a plurality of original images according to some implementations.

Referring to FIGS. 6A to 6C, a semiconductor manufacturing device 100 may include an objective lens 101, a stage 102, and an object 103. The objective lens 101, the stage 102, and the object 103 may correspond to the objective lens 33, the stage 70, and the object 90, described with reference to FIG. 1, respectively.

The object 103 may be positioned upon the stage 102, and a controller of the semiconductor manufacturing device 100 may be configured to change a working distance of the objective lens 101 to first to third working distances WD1 to WD3, to acquire a plurality of original images 111, 112, and 113. An electron beam collector 104 may be provided on one side of the objective lens 101 close to the object 103. The working distance may be defined as a distance between the one side of the objective lens 101 and the object 103.

Referring to FIG. 6A, in a state in which the objective lens 101 is located at the first working distance WD1, the controller may be configured to acquire a first original image 111. The first working distance WD1 may be shorter than a focal distance of the objective lens 101, and the first original image 111 may be an image captured under an underfocused condition.

Next, referring to FIG. 6B, in a state in which the objective lens 101 is located at the second working distance WD2, the controller may be configured to acquire a second original image 112. The second working distance WD2 may substantially coincide with the focal distance of the objective lens 101, and thus structures included in the object may be displayed relatively clearly in the second original image 112.

Referring to FIG. 6C, in a state in which the objective lens 101 is located at the third working distance WD3, the controller may be configured to acquire a third original image 113. For example, the third working distance WD3 may be longer than the focal distance of the objective lens 101, and the third original image 113 may be an image captured under an overfocused condition.

As described with reference to FIGS. 6A to 6C, the controller of the semiconductor manufacturing device 100 may be configured to acquire the plurality of original images 111, 112, and 113 while changing the working distance of the objective lens. As described above, when an axis of an electron beam and a position of an aperture are misaligned, the imaging region may move according to the working distance of the objective lens. When an imaging region moves, relative positions of patterns included in the plurality of original images 111, 112, and 113 may appear to move.

For example, referring to the plurality of original images 111, 112, and 113 together, as the working distance of the objective lens increases from the first working distance WD1 to the third working distance WD3, checkered pattern may move in a left downward direction.

According to some implementations, a position vector indicating a degree of movement of a relative position of a pattern in the plurality of original images may be acquired.

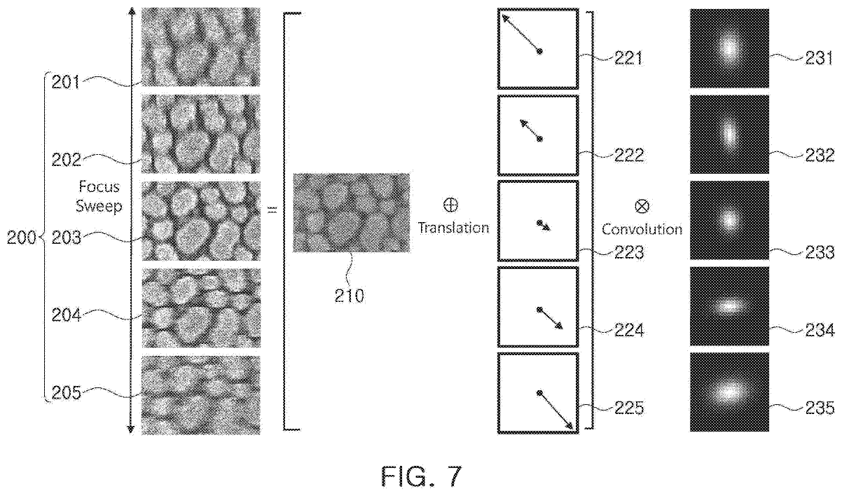

FIGS. 7 to 9 are views illustrating a method of acquiring a plurality of position vectors from a plurality of original images according to some implementations.

Referring to FIG. 7, a plurality of original images 201 to 205 acquired by irradiating an electron beam onto an imaging region of an object at various working distances are illustrated. A third original image 203 may be an image captured at a working distance, similar to a focal distance of an objective lens, and structures included in the imaging region of the object may be displayed most clearly in the third original image 203.

First and second original images 201 and 202 may be images captured under underfocused conditions and compared to the third original image 203, and the imaging region may move. As compared to patterns displayed in the third original image 203, patterns of the first and second original images 201 and 202 may be displayed blurry, and positions thereof may move.

Fourth and fifth original images 204 and 205 may be images captured under overfocused conditions, and, as compared to the patterns illustrated in the third original image 203, patterns thereof may be displayed blurry, and positions thereof may move in a direction, opposite to that of the first and second original images 201 and 202.

The plurality of original images 201 to 205 may have different relative positions and sharpness of patterns, but the plurality of original images 201 to 205 may include patterns indicating the same structures. For example, each of the plurality of original images 201 to 205 may be acquired by applying a plurality of different position vectors 221 to 225 and a plurality of different kernel images 231 to 235 to a pattern image 210.

The pattern image may be an image displaying structures formed in a target region to be imaged in the object, the plurality of position vectors may be vectors indicating a direction and a magnitude of movement of structures appearing in a pattern image in the original images, and the plurality of kernel images may be images indicating distribution of electron beams irradiated to the imaging region of the object.

A shifting operation using each of the plurality of position vectors 221 to 225 may be performed on the pattern image 210, and a convolutional operation using the plurality of kernel images 231 to 235 may be performed on shifted images, respectively, to acquire the plurality of original images 201 to 205.

Conversely, a deconvolutional operation may be applied to each of the plurality of original images 201 to 205 to acquire the pattern image 210, the plurality of position vectors 221 to 225, and the plurality of kernel images 231 to 235.

Since the pattern image 210, the plurality of position vectors 221 to 225, and the plurality of kernel images 231 to 235 may be unknown values, estimation of the pattern image 210, estimation of each of the plurality of position vectors 221 to 225, and estimation of each of the plurality of kernel images 231 to 235 may be required.

According to some implementations, an objective function F for optimizing deconvolution for estimating the pattern image 210, the plurality of position vectors 221 to 225, and the plurality of kernel images 231 to 235 may be expressed as Equation 1, as follows:

$$F = {min}_{u , {Σ}_{1} , ⋯ , {Σ}_{N} , {v}_{1} , ⋯ , {v}_{N}} \frac{1}{N} {\sum }_{i = 1}^{N} \vert \vert {k}_{{Σ}_{i}} ⋆ u ( x + {v}_{i} ) - {f}_{i} {‖}_{2}^{2} + λ ‖ ∇ u {‖}_{1}^{1} \qquad [ Equation 1 ]$$

In Equation 1, fᵢ may correspond to an i^{th} original image among the plurality of original images 201 to 205, u may correspond to the pattern image 201, vᵢ may correspond to an i^{th} position vector among the plurality of position vectors 221 to 225, and k_{Σi} may correspond to an i^{th} kernel image among the plurality of kernel images 231 to 235. Additionally, k may be a balancing parameter.

The following assumptions may be applied to Equation 1. First, it may be assumed that the position vector vᵢ is constant in all pixels of the original image fᵢ. For example, it is assumed that the structures illustrated in the pattern image u have moved to the same position and direction in the original image fᵢ. Second, it may be assumed that the kernel image k_{Σi} is defined as a point spread function having a Gaussian distribution Σᵢ. Third, it may be assumed that structures displayed on the pattern image u have sharp characteristics.

Equation 1 may be explained as follows. The objective function F may be a function for finding the pattern image 210, the plurality of position vectors 221 to 225, and the plurality of kernel images 231 to 235, capable of minimizing a sum of an average of differences between calculated images calculated by respectively using the pattern image 210, the plurality of position vectors 221 to 225, and the plurality of kernel images 231 to 235, and the plurality of original images 201 to 205, and a gradient Vu of the pattern image.

In this case, the calculated images may be referred to results k_{Σ}_{ᵢ}*u(x+vᵢ) acquired by performing the convolutional operation using the kernel image k_{Σi} on the image acquired by moving the pattern image u by the position vector vᵢ. Also, the gradient ∇u of the pattern image u may represent a degree of sharpness of the pattern image u. As the pattern image u is sharpened, the gradient ∇u may decrease.

In short, the pattern image 210, the plurality of position vectors 221 to 225, and the plurality of kernel images 231 to 235 may be generated while the pattern image 210 may be sharpened to some extent by using the objective function F. The pattern image 210, the plurality of position vectors 221 to 225, and the plurality of kernel images 231 to 235 may be optimized such that the calculated images may be similar to the plurality of original images 201 to 205.

From Equation 1, Equation 2 for extracting the pattern image u, Equation 3 for extracting the Gaussian distribution Σᵢ, and Equation 4 for extracting the position vector vᵢ may be derived as follows:

$$u ← u - {ϵ}_{u} \frac{\partial {F}_{u}}{\partial u} , \qquad [ Equation 2 ]$$

$$\frac{\partial {F}_{u}}{\partial u} = \frac{1}{n} {\sum }_{i = 0}^{n} [ \overline{{k}_{{Σ}_{l}}} ⊗ ( {k}_{{Σ}_{i}} ⊙ u ( x + {v}_{i} ) - {f}_{i} ) ] - λ ∇ \cdot \frac{∇ u}{\vert ∇ u \vert}$$

Equation 2 represents an equation for updating the pattern image u by applying a gradient descent to a previous pattern image u. In Equation 2, ⊙ may represent a valid convolution, ⊗ may represent a full padding convolution, and k̅_̅{̅Σ̅}̅_̅{̅ᵢ̅}̅ may represent an image in which an (x, y) value of the kernel image k_{Σi} is inverted:

$${Σ}_{i} ← {Σ}_{i} - {ϵ}_{Σ} \frac{\partial {F}_{{Σ}_{i}}}{\partial {Σ}_{i}} , \frac{\partial {k}_{{Σ}_{i}}}{\partial {Σ}_{i}} = \frac{1}{K} {\int }_{x} - \frac{1}{2} {k}_{Σ} ( x ) ( {Σ}^{- 1} - {Σ}^{- 1} x {x}^{T} {Σ}^{- 1} ) d x \qquad [ Equation 3 ]$$

Equation 3 represents an equation for updating the Gaussian distribution Σᵢ by applying the gradient descent to a previous Gaussian distribution Σᵢ. In Equation 3, K may represent a size of the kernel image:

$${v}_{i 1} ← - \frac{{Σ}_{p i x e l s} [ ( {k}_{{Σ}_{i}} * {u}_{x} ) \cdot ( {k}_{{Σ}_{i}} * ( {v}_{i 2} {u}_{y} + u ) - {f}_{i} ) ]}{{‖k}_{{Σ}_{i}} * {u}_{x} {‖}_{2}^{2}} , \qquad [ Equation 4 ]$$

$${v}_{i 2} ← - \frac{{Σ}_{p i x e l s} [ ( {k}_{{Σ}_{i}} * {u}_{y} ) \cdot ( {k}_{{Σ}_{i}} * ( {v}_{i 1} {u}_{x} + u ) - {f}_{i} ) ]}{{‖k}_{{Σ}_{i}} * {u}_{y} {‖}_{2}^{2}}$$

Equation 4 represents an equation for updating an x-axis component vᵢ₁ and a y-axis component vᵢ₂ of the motion vector vᵢ, respectively. Specifically, Equation 4 represents a mathematical expression for acquiring a vii value for which a value acquired by differentiating the objective function F by vᵢ₁ is ‘0,’ and a vᵢ₂ value for which a value acquired by differentiating the objective function F by vᵢ₂ is ‘0,’ based on an updated kernel image k_{Σi} and the pattern image u.

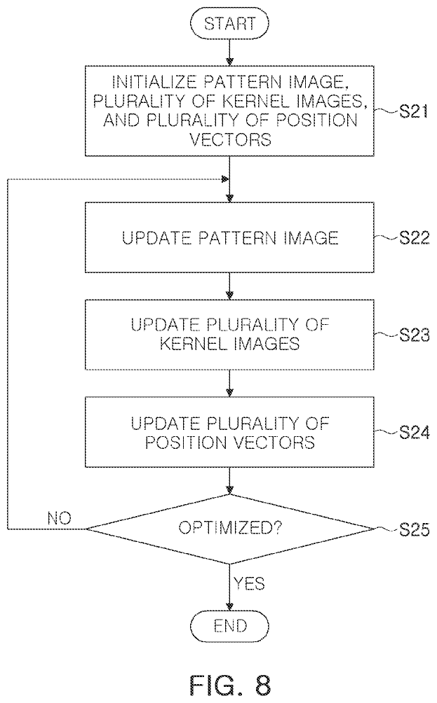

A method of optimizing the pattern image u, the Gaussian distribution Σᵢ, and the position vector vᵢ by applying Equation 2, Equation 3, and Equation 4 will be described with reference to FIG. 8.

Referring to FIG. 8, in operation S21, a controller of a semiconductor manufacturing device may initialize a pattern image 210, a plurality of position vectors 221 to 225, and a plurality of kernel images 231 to 235. To optimize a pattern image u and a Gaussian distribution Σᵢ by applying a gradient descent to Equation 2 and Equation 3, an initial value for the pattern image 210, an initial value for each of the plurality of position vectors 221 to 225, and an initial value for each of the plurality of kernel images 231 to 235 needs to be selected.

According to some implementations, the initial value of the pattern image 210 may be set to a random noise image, the initial value of each of the plurality of position vectors 221 to 225 may be set to a zero vector, and the initial value of each of the plurality of kernel images 231 to 235 may be set to a non-directional Gaussian distribution function.

In operation S22, the controller may update the pattern image 210 by applying Equation 2. In operation S23, the controller may update the plurality of kernel images 231 to 235 by updating the Gaussian distribution Σᵢ by applying Equation 3. In operation S24, the controller may update the plurality of position vectors 221 to 225 by applying Equation 4.

In operation S25, the controller may determine whether the pattern image 210, the plurality of kernel images 231 to 235, and the plurality of position vectors 221 to 225 are optimized. For example, as a result of performing operations S22 to S24, the controller determines whether difference values between previous values and updated values of the pattern image 210, the plurality of kernel images 231 to 235, and the plurality of position vectors 221 to 225 are smaller than a threshold value, respectively.

When each of the difference values is smaller than the threshold value, it may be determined that the values of the pattern image 210, the plurality of kernel images 231 to 235, and the plurality of position vectors 221 to 225 have converged to optimized values according to a gradient descent. Therefore, the controller may determine that the pattern image 210, the plurality of kernel images 231 to 235, and the plurality of position vectors 221 to 225 are optimized (“Yes” in operation S25), and may end the operation.

When each of the difference values is greater than or equal to the threshold value, the controller may determine that the pattern image 210, the plurality of kernel images 231 to 235, and the plurality of position vectors 221 to 225 have not been optimized (“No” in operation S25), operations S22 to S24 may be iteratively performed until the pattern image 210, the plurality of kernel images 231 to 235, and the plurality of position vectors 221 to 225 are optimized.

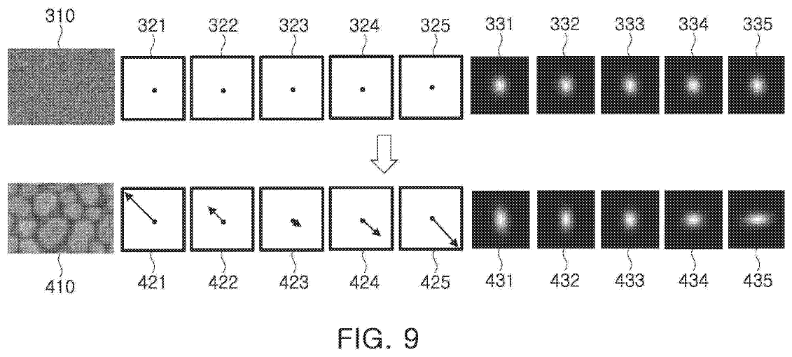

Referring to FIG. 9, a pattern image 310 may be initialized as a random noise image, and a certain structure may not appear in the initialized pattern image 310. A plurality of position vectors 321 to 325 may be initialized to zero vectors, and movement of a pattern may not appear in the plurality of position vectors 321 to 325. In addition, a plurality of kernel images 331 to 335 may be initialized to non-directional Gaussian distribution functions, and the distribution of electron beams in each of the plurality of kernel images 331 to 335 may appear in a form of the same point spread function.

The pattern image 310 may be updated by iteratively performing optimization based on original images 201 to 205, as illustrated in FIG. 7, and finally a pattern image displaying structures included in a target region of an object 410 may be acquired. Similarly, a plurality of position vectors 421 to 425 having different directivity may be acquired by updating the plurality of position vectors 321 to 325 having a zero vector. In addition, the plurality of kernel images 331 to 335 in a form of a point spread function may be updated to acquire a plurality of kernel images 431 to 435 represented by a two-dimensional Gaussian distribution function having different distributions.

According to some implementations, a pattern image, a plurality of kernel images, and a plurality of position vectors may be accurately separated from a plurality of original images. For example, in an objective lens of a semiconductor manufacturing device having astigmatism, when a working distance and a focal distance are accurately coincided, distribution of electron beams may have a circular shape, but under an underfocused condition, the distribution of the electron beams may have a shape extending in a first direction, and under an overfocused condition, and the distribution of the electron beams may have a shape extending in a second direction, perpendicular to the first direction. Therefore, structures in the plurality of original images may have different shapes, and it may be difficult to accurately determine a movement direction and a size thereof with a naked eye.

According to some implementations, a pattern image extracted from a plurality of original images may have sharp-shaped patterns. In addition, distribution of electron beams may extend perpendicularly to each other in images under an underfocused condition and images under an overfocused condition, among kernel images extracted from the plurality of original images. For example, a pattern image and a plurality of kernel images may be accurately extracted from a plurality of original images. In addition, a plurality of position vectors may be extracted from the plurality of original images by removing influence of a shape of the pattern and shapes of the electron beams due to astigmatism.

Therefore, position vectors of patterns for each working distance may be acquired using a plurality of original images, regardless of a pattern of structures included in a target region of an object or astigmatism of an objective lens of a semiconductor manufacturing device.

A controller of a semiconductor manufacturing device may acquire motion vectors of patterns according to the working distance based on the acquired position vectors, and may acquire a compensation vector for determining a compensation direction of an aperture position based on the acquired motion vectors. In the following, a method of acquiring a motion vector and a compensation vector will be described in more detail.

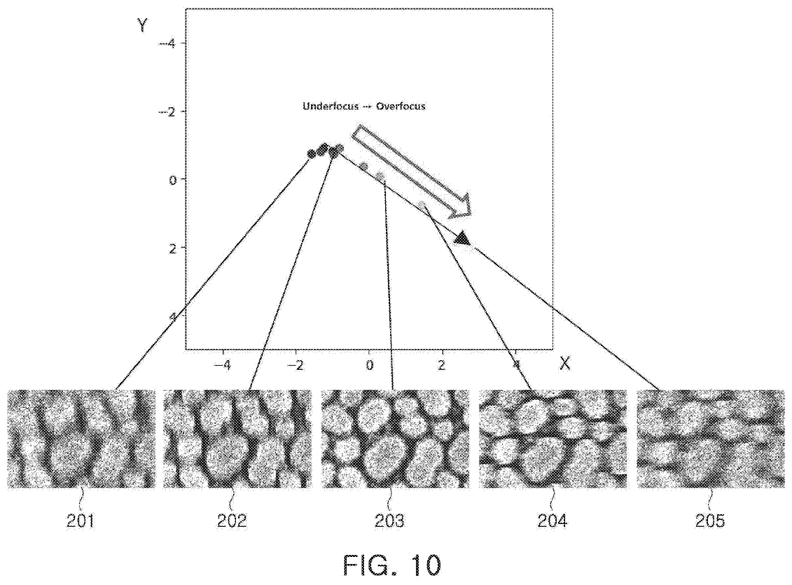

FIG. 10 is a view illustrating a method of acquiring a motion vector from a plurality of position vectors according to some implementations.

In a graph of FIG. 10, a plurality of position vectors according to a working distance of an objective lens are illustrated as dots. Specifically, each point represents an end point of a position vector with an origin (0, 0) as a starting point.

The plurality of position vectors may have a certain tendency according to the working distance of the objective lens. In an example of FIG. 10, when the working distance of the objective lens is changed from an underfocused condition to an overfocused condition as the working distance gradually increases from a state closer than a focal distance, the end points of the position vectors may tend to move from upper left to lower right. For example, referring to a plurality of original images 201 to 205 according to the working distance of the objective lens, patterns may move from the upper left to the lower right as the working distance gradually increases.

A controller of a semiconductor manufacturing device may acquire a motion vector indicating a motion direction of the plurality of position vectors by using a principal component analysis (PCA) technique. Specifically, the controller may generate one-dimensional data indicating movement of the plurality of position vectors based on the plurality of position vectors distributed in the two-dimensional graph. And, the controller may determine a direction of the one-dimensional data as the direction of the motion vector.

The controller may determine a size of the motion vector based on a standard deviation of the plurality of position vectors. For example, when positions of the end points of the position vectors vary greatly according to the working distance of the objective lens, the standard deviation of the plurality of position vectors may increase. Therefore, the controller may determine that the size of the motion vector is proportional to the standard deviation of the plurality of position vectors.

Hereinafter, a method of acquiring a compensation vector for compensating for a position of an aperture based on the motion vector will be described.

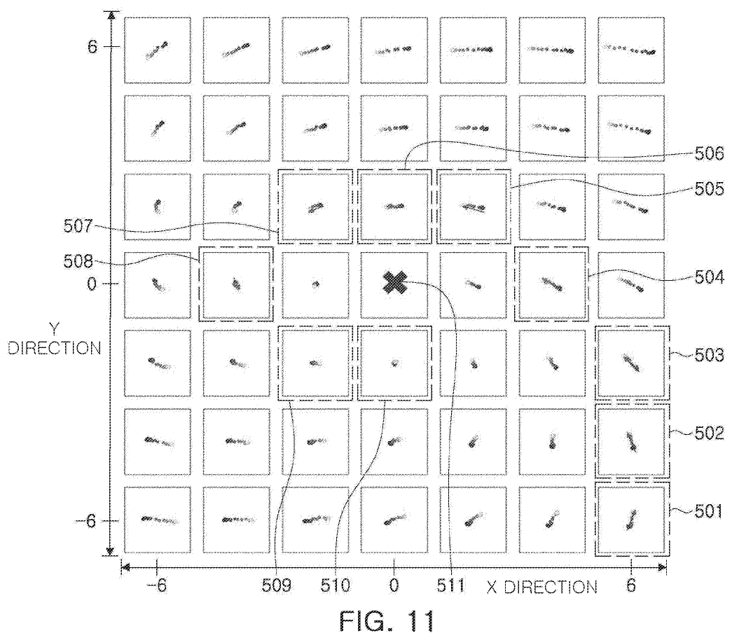

FIG. 11 is a view illustrating a motion vector according to a position of an aperture on an X-Y plane.

In FIG. 11, a horizontal axis may represent an X-direction position of an aperture, and a vertical axis may represent a Y-direction position of the aperture. Referring to FIG. 11, a plurality of graphs may be arranged in a matrix form along the horizontal axis and the vertical axis. Each of the plurality of graphs illustrates motion vectors according to a working distance of an objective lens at different positions of the aperture.

Among the positions of the aperture, the aperture may be substantially aligned with an axis at a position in which a motion vector is close to a zero vector. FIG. 11 illustrates an alignment position 511, which may be a position in which the aperture is accurately aligned to the axis. As the position of the aperture moves away from the alignment position 511, a magnitude of the motion vector at the position may tend to increase.

Referring to directions of motion vectors illustrated in the plurality of graphs together, the motion vectors may have a tendency to converge to the alignment position 511 along a spiral path. For example, in the aperture at a first position 501 having coordinates of (6, −6), when the position of the aperture moves by a magnitude and a direction of a motion vector at the first position 501, the aperture may be placed at a second position 502. Also, in the aperture at the second position 502, when the position of the aperture moves by a magnitude and a direction of a motion vector at the second position 502, the aperture may be placed at a third position 503. When an operation of moving the aperture by a magnitude and a direction of a motion vector at the current position is iteratively performed until the magnitude of the motion vector is smaller than a threshold magnitude, the position of the aperture may converge to the alignment position 511 through fourth to tenth positions 504 to 510.

Even in the aperture located at a position other than the first position 501, when an operation of moving the position of the aperture is iteratively performed by a magnitude and a direction of a motion vector at a position corresponding thereto, the aperture may be located at the alignment position 511.

According to some implementations, the controller may capture a plurality of original images according to the working distance of the objective lens at the current position of the aperture to acquire a motion vector, and may determine a movement direction and a size of the aperture based on the motion vector. The aperture may be controlled to reach the alignment position by acquiring a compensation vector and iteratively performing an operation of moving the aperture based on the compensation vector at the current position of the aperture, until the motion vector is smaller than a threshold magnitude.

In the example of FIG. 11, a direction of the compensation vector of the aperture may be equal to a direction of the motion vector of the aperture at the current position. However, the subject matter of the present disclosure is not limited thereto. According to some implementations, the direction of the compensation vector of the aperture may be acquired by rotating the direction of the motion vector at a predetermined angle, and the predetermined angle may be selected from a range of angles such that directions of the compensation vectors according to a position of the aperture may converge to one position of the aperture. For example, the controller may determine the predetermined angle such that the position of the aperture may reach the alignment position with fewer iterations.

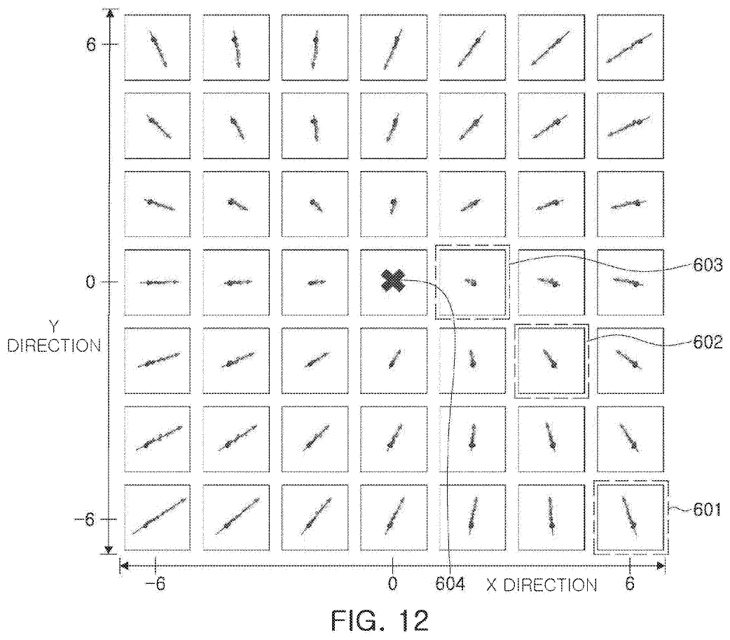

FIG. 12 is a view illustrating a compensation vector according to a position of an aperture on an X-Y plane.

In FIG. 12, a horizontal axis may represent an X-direction position of an aperture, and a vertical axis may represent a Y-direction position of the aperture. Referring to FIG. 12, a plurality of graphs may be arranged in a matrix form along the horizontal axis and the vertical axis. Each of the plurality of graphs illustrates compensation vectors at different positions of the aperture.

According to some implementations, a compensation vector according to a position of the aperture may be acquired by rotating a motion vector according to the position of the aperture by a predetermined angle. Referring to FIGS. 11 and 12 together, the compensation vectors illustrated in FIG. 12 may be acquired by collectively rotating the motion vectors illustrated in FIG. 11 by 45 degrees counterclockwise.

In the aperture at a first position 601, when the position of the aperture may move by a magnitude and a direction of the compensation vector at the first position 601, the aperture may be placed at a second position 602. When an operation of moving the aperture by a magnitude and a direction of the compensation vector at the current position may be iteratively performed until the magnitude of the motion vector is smaller than a threshold magnitude, the position of the aperture may converge to an alignment position 604 through a third position 603. Therefore, in FIG. 12, the position of the aperture may converge to the alignment position with a smaller number of iterations, as compared to FIG. 11.

The motion vectors in FIG. 11 may converge to the alignment position along a spiral path, and the compensation vectors in FIG. 12 may converge to the alignment position along a straight path. A rotation angle for acquiring a compensation vector may be experimentally acquired. For example, the rotation angle may be selected such that motion vectors with spiral paths have paths close to straight lines.

According to some implementations, a controller may control the position of the aperture to reach the alignment position even when a semiconductor manufacturing device has astigmatism.

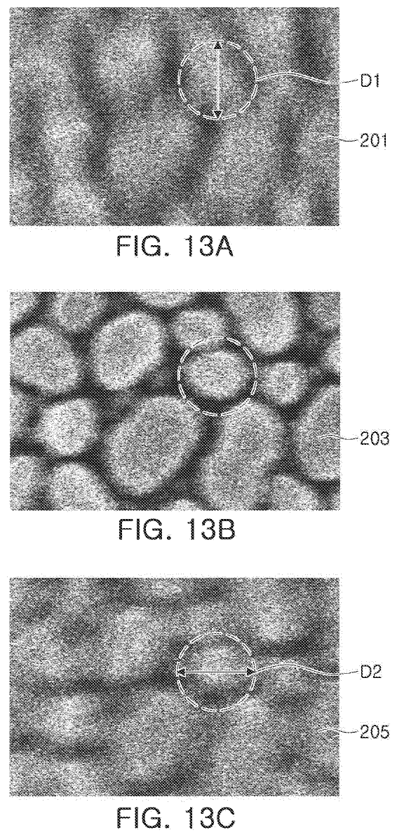

FIGS. 13A to 13C are views illustrating original images according to a working distance, when a semiconductor manufacturing device has astigmatism.

An original image 201 of FIG. 13A may be an image under an underfocused condition, an original image 203 of FIG. 13B may be an image at a focal distance, and an original image 205 of FIG. 13C may be an image under an overfocused condition. Referring to FIGS. 13A to 13C, a pattern having a substantially circular shape at the focal distance may have a shape extending in a first direction D1 under the underfocused condition, and may have a shape extending in a second direction D2, perpendicular to the first direction, under the overfocused condition.

When a semiconductor manufacturing device has astigmatism, due to shapes of patterns in a plurality of original images, the plurality of original images may appear as if the patterns rotate and move according to a working distance. For example, comparing the original image 201 and the original image 205, the same pattern may appear to move in a right and downward direction while rotating 90 degrees. Position vectors acquired from the original images may also have a curved distribution.

According to some implementations, a position of an aperture may be corrected to an alignment position, regardless of a shape of distribution of the position vectors due to astigmatism.

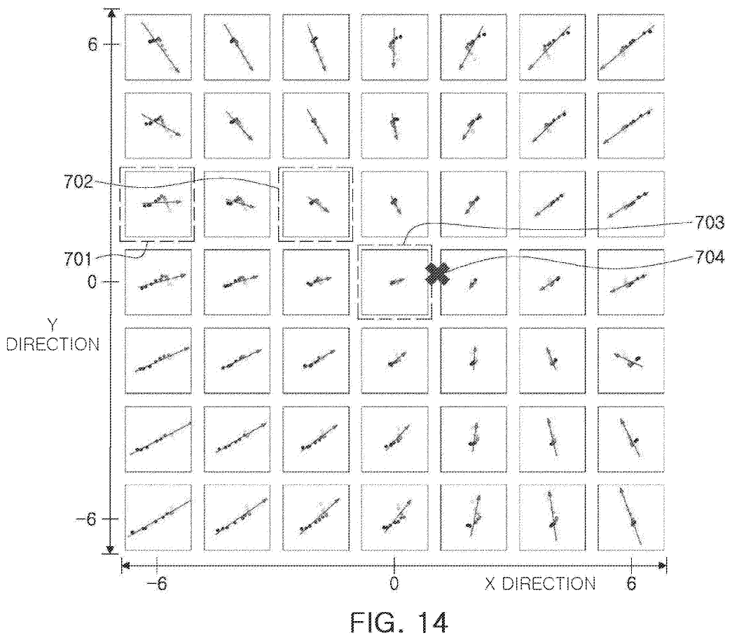

FIG. 14 is a view illustrating a compensation vector according to a position of an aperture on an X-Y plane, when a semiconductor manufacturing device has astigmatism.

In FIG. 14, a horizontal axis may represent an X-direction position of an aperture, and a vertical axis may represent a Y-direction position of the aperture. Referring to FIG. 14, a plurality of graphs may be arranged in a matrix form along the horizontal axis and the vertical axis. Each of the plurality of graphs illustrates distribution of position vectors and compensation vectors according to a working distance of an objective lens at different positions of the aperture. In FIG. 14, the compensation vectors are illustrated as arrows. In addition, the position vectors are illustrated as dots, and are illustrated to rotate at the same angle as a rotation angle of a compensation vector on a graph.

Referring to FIG. 14, position vectors at various positions of the aperture may have a curved distribution rather than a linear distribution. For example, referring to the graph at the first position 701, position vectors may have a bent distribution.

According to some implementations, a controller may acquire a motion vector from the position vectors using a PCA technique, and may thus acquire a linear motion vector regardless of the distribution of the position vectors. In addition, the controller may acquire the linear compensation vector by rotating the motion vector by a predetermined rotation angle.

Referring to FIG. 14, although the distribution of the position vectors is curved due to astigmatism of a semiconductor manufacturing device, the compensation vectors may converge to an alignment position 704.

For example, when a compensation vector is acquired based on position vectors in the aperture at a first position 701 and a position of the aperture moves by a magnitude and a direction of the compensation vector, the aperture may be placed at a second position 702. And, when a position of the aperture in the aperture at the second position 702 moves by a magnitude and a direction of the compensation vector, the aperture may converge to a third position 703 close to the alignment position 704.

According to some implementations, a controller of a semiconductor manufacturing device may align an aperture on a vertical axis, based on a motion vector acquired using a plurality of original images according to a working distance of an objective lens regardless of whether the semiconductor manufacturing device has astigmatism or not. The controller may fix an imaging region when adjusting the working distance of the objective lens by aligning the aperture. Therefore, the semiconductor manufacturing device may quickly acquire an image of a target region to be imaged.

The controller may acquire a plurality of kernel images along with a plurality of position vectors based on the plurality of original images. The controller may calculate a motion vector based on the plurality of position vectors to align the aperture, and may adjust a stigmator based on the plurality of kernel images to improve stigmatism.

In addition, according to some implementations, since an operation of aligning an aperture may be automated, the aperture may be aligned quickly and accurately, as compared to manually adjusting a position of the aperture, and a variance in alignment of the aperture between semiconductor production devices may also be reduced.

According to some implementations, a controller may include at least one of a central processing unit (CPU) and a graphics processing unit (GPU), wherein the graphics processing unit may execute an operation of acquiring a pattern image, a plurality of kernel images, and a plurality of position vectors from a plurality of original images. Since the graphics processing unit (GPU) may be specialized in parallel operation, compared to the central processing unit (CPU), operations for images may be parallelized and processed quickly. Therefore, an operation of aligning an aperture may be performed more quickly.

According to some implementations, a device using an electron beam may change a working distance between a lens and an object, may detect misalignment between the electron beam and an aperture using a plurality of original images acquired, and may adjust a position of the aperture for compensating for the misalignment. Since the position control of the aperture may be automated, efficiency of a semiconductor process using the electron beam may be improved.

Problems to be solved by the subject matter of the present disclosure are not limited to the problems mentioned above, and other problems not mentioned will be clearly understood by those skilled in the art from the description below.

While example implementations have been illustrated and described above, it will be apparent to those skilled in the art that modifications and variations could be made without departing from the scope of the present disclosure as defined by the appended claims.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

What is claimed is:

1. A semiconductor manufacturing device comprising:
an electron beam source configured to emit an electron beam;
a plurality of condenser lenses disposed between a stage and the electron beam source, wherein the stage is configured to support an object;
an objective lens disposed between the plurality of condenser lenses and the stage;
an aperture disposed between the plurality of condenser lenses; and
a controller configured to
acquire a plurality of original images according to a working distance between the objective lens and the object,
acquire a pattern image from the plurality of original images, wherein the pattern image exhibits object features corresponding to structures from the object,
acquire a plurality of kernel images indicating distribution of the electron beam on the object,
acquire a plurality of position vectors indicating a relative position of the object features in the plurality of kernel images, and
adjust a position of the aperture based on a motion vector indicating movement of the plurality of position vectors according to the working distance.

2. The semiconductor manufacturing device of claim 1, wherein the plurality of original images comprise:
at least one overfocused image captured under an overfocused condition in which the working distance is longer than a focal distance of the objective lens, and
at least one underfocused image captured under an underfocused condition in which the working distance is shorter than the focal distance of the objective lens.

3. The semiconductor manufacturing device of claim 1, wherein each original image of the plurality of original images corresponds to a convolution between images having been moved by application of each position vector of the plurality of position vectors to the pattern image and each kernel image of the plurality of kernel images, and
wherein the controller is configured to apply a deconvolutional operation to each original image of the plurality of original images.

4. The semiconductor manufacturing device of claim 1, wherein the controller is configured to acquire the pattern image, the plurality of kernel images, and the plurality of position vectors using an objective function capable of minimizing a sum of (i) a gradient of the pattern image and (ii) an average of differences between the plurality of original images and calculated images,
wherein the calculated images are calculated by performing a convolutional operation using each kernel image of the plurality of kernel images on images having been moved by application of each position vector of the plurality of position vectors to the pattern image.

5. The semiconductor manufacturing device of claim 4, wherein the controller is configured to:
define the plurality of kernel images as a point spread function having a Gaussian distribution, and
define components of the plurality of position vectors as a constant having the same value in any pixel of the pattern image, respectively.

6. The semiconductor manufacturing device of claim 4, wherein the controller is configured to apply a gradient descent to the objective function for the pattern image to update the pattern image, apply a gradient descent to the objective function for each of the plurality of kernel images to update each of the plurality of kernel images, differentiate the objective function with each of the components of the plurality of position vectors, and obtain a component of the plurality of position vectors for which a differential value is 0 to update the plurality of position vectors.

7. The semiconductor manufacturing device of claim 6, wherein the controller is configured to iteratively perform the following operations until a difference value before and after the operations are performed is smaller than a threshold value:
an operation of updating the pattern image,
an operation of updating each of the plurality of kernel images, and
an operation of updating the plurality of position vectors.

8. The semiconductor manufacturing device of claim 6, wherein the controller is configured to:
initialize the pattern image to a random noise image;
initialize each of the plurality of kernel images to a point spread function having a non-directional Gaussian distribution; and
initialize each of the plurality of position vectors to a zero vector.

9. The semiconductor manufacturing device of claim 1, wherein the controller comprises a central processing unit (CPU) and a graphics processing unit (GPU),
wherein the graphics processing unit is configured to execute an operation of acquiring the pattern image, the plurality of kernel images, and the plurality of position vectors from the plurality of original images.

10. The semiconductor manufacturing device of claim 1, wherein the objective lens further comprises a stigmator configured to adjust astigmatism,
wherein the controller is configured to adjust the stigmator based on the plurality of kernel images.

11. A semiconductor manufacturing device comprising:
an electron beam source configured to emit an electron beam;
a lens unit configured to transfer the electron beam to an object;
an aperture configured to limit an electron beam path of the lens unit; and
a controller configured to
acquire a plurality of original images according to a working distance between the lens unit and the object,
acquire a plurality of position vectors indicating a relative position, in the plurality of original images, of structures of an object,
calculate a motion vector indicating movement of the plurality of position vectors according to the working distance, and
adjust a position of the aperture according to a compensation vector determined based on the motion vector.

12. The semiconductor manufacturing device of claim 11, wherein the controller is configured to apply a principal component analysis (PCA) technique to the plurality of position vectors, and determine a direction of the motion vector.

13. The semiconductor manufacturing device of claim 12, wherein the controller is configured to determine a size of the motion vector based on a standard deviation of distribution of the plurality of position vectors.

14. The semiconductor manufacturing device of claim 11, wherein the controller is configured to determine the compensation vector such that the compensation vector has a direction equal to a direction of the motion vector, and has a magnitude proportional to a magnitude of the motion vector.

15. The semiconductor manufacturing device of claim 11, wherein the controller is configured to determine the compensation vector such that the compensation vector has a direction determined by rotating a direction of the motion vector at a predetermined angle, and has a magnitude proportional to a magnitude of the motion vector.

16. The semiconductor manufacturing device of claim 15, wherein the predetermined angle is an angle that a direction of the compensation vector according to a position of the aperture converges to one position.

17. The semiconductor manufacturing device of claim 11, wherein the controller is configured to iteratively perform the following operations until a magnitude of the motion vector is smaller than a threshold magnitude:
an operation of adjusting the position of the aperture using the motion vector,
an operation of acquiring the plurality of original images, and
an operation of acquiring the plurality of position vectors.

18. A semiconductor manufacturing device comprising:
an electron beam source configured to emit an electron beam;
a plurality of condenser lenses disposed between a stage and the electron beam source, wherein the stage is configured to support an object;
an objective lens disposed between the plurality of condenser lenses and the stage;
an aperture disposed between the plurality of condenser lenses; and
a controller configured to
acquire a plurality of original images according to a working distance between the object and the objective lens configured to transfer an electron beam to the object,
acquire a single pattern image indicating structures included in the object,
acquire a plurality of kernel images indicating distribution of the electron beam on the object,
acquire a plurality of position vectors indicating a relative position of the structures in the plurality of original images, from the plurality of original images;
acquire a motion vector indicating a movement direction according to the working distance, based on the plurality of position vectors;
determine a compensation vector based on the motion vector; and
move a position of an aperture limiting an electron beam path of the lens unit based on the compensation vector.

19. The semiconductor manufacturing device of claim 18, wherein the controller acquires the single pattern image, the plurality of kernel images, and the plurality of position vectors from the plurality of original images, by:
initializing the single pattern image to a random noise image;
initializing each kernel image of the plurality of kernel images to a point spread function having a non-directional Gaussian distribution;
initializing each position vector of the plurality of position vectors to a zero vector;
updating the single pattern images by applying a gradient descent to an objective function for optimizing a convolution between each images moved by applying each position vector of the plurality of position vectors to the single pattern image and each kernel image of the plurality of kernel images, and a difference value between each original image of the plurality of original images;
updating each kernel image of the plurality of kernel images by applying a gradient descent to the objective function; and
updating the plurality of position vectors such that a function acquired by differentiating the objective function has a value of 0.

20. The semiconductor manufacturing device of claim 19, wherein the controller acquires the single pattern image, the plurality of kernel images, and the plurality of position vectors from the plurality of original images, by:
iteratively performing the following operations until a difference value before and after the operations are performed is smaller than a threshold value:
an operation including updating the single pattern image;
updating the plurality of kernel images; and
updating the plurality of position vectors.
